(19) United States
(12) Patent Application Publication
(10) Pub. No.: US 2025/0224826 A1
(43) Pub. Date: Jul. 10, 2025

(54) DISPLAY DEVICE

(71) Applicant: Samsung Display Co., LTD., Yongin-si, Gyeonggi-do (KR)

(72) Inventors: Soo Won KIM, Yongin-si (KR); Young Seok YOO, Yongin-si (KR); Hyun Jae LEE, Yongin-si (KR)

(21) Appl. No.: 18/927,609

(22) Filed: Oct. 25, 2024

(30) Foreign Application Priority Data
Jan. 9, 2024 (KR) 10-2024-0003514

(51) Int. Cl. G06F 3/041

(52) U.S. Cl. CPC G06F 3/0416; G06F 3/0412

(57) ABSTRACT

A display device includes: a touch panel to sense a touch; and a touch panel driver to drive the touch panel, the touch panel driver including: pins including a first pin and a second pin to receive a signal corresponding to the touch from the touch panel; signal receivers connected to the pins, respectively; and a first analog-digital converter connected to a signal receiver connected to the first pin from among the signal receivers, the first analog-digital converter being configured to output a first signal or a second signal according to a magnitude of an input signal of the first analog-digital converter.

### CROSS-REFERENCE TO RELATED APPLICATION

The present application claims priority to and the benefit of Korean patent application No. 10-2024-0003514, filed on Jan. 9, 2024, in the Korean Intellectual Property Office, the entire disclosure of which is incorporated by reference herein.

### BACKGROUND

### 1. Field

Aspects of embodiments of the present disclosure relate to a display device, and more particularly, to a display device for recognizing a touch.

### 2. Description of the Related Art

Electronic devices, which have touch panels mounted therein to have a function capable of indicating a position through a touch, are widely used. As mobile electronic devices such as smartphones and tablet computers come into use, touch panels are widely used.

A touch panel is driven by a touch panel driver. The touch panel driver may include a certain number of pins in a production process. When a number of touch electrodes of the touch panel is greater by even one more than the number of pins of the touch panel driver, which are to be used, a touch panel driver having a larger number of pins may be used. In addition, any pin for transmitting/receiving a synchronization signal may not be included in a specific touch panel driver.

The above information disclosed in this Background section is for enhancement of understanding of the background of the present disclosure, and therefore, it may contain information that does not constitute prior art.

### SUMMARY

One or more embodiments of the present disclosure may be directed to a display device that utilizes a pin for recognizing a touch signal for another use.

One or more embodiments of the present disclosure may be directed to a display device that utilizes a pin connected to an interface circuit for another use.

According to one or more embodiments of the present disclosure, a display device includes: a touch panel configured to sense a touch; and a touch panel driver configured to drive the touch panel, the touch panel driver including: pins including a first pin and a second pin configured to receive a signal corresponding to the touch from the touch panel; signal receivers connected to the pins, respectively; and a first analog-digital converter connected to a signal receiver connected to the first pin from among the signal receivers, the first analog-digital converter being configured to output a first signal or a second signal according to a magnitude of an input signal of the first analog-digital converter.

In an embodiment, the display device may further include a second analog-digital converter connected to a signal receiver connected to the second pin from among the signal receivers, the second analog-digital converter being configured to convert an input signal of the second analog-digital converter into a digital signal corresponding to a voltage level of the input signal of the second analog-digital converter.

In an embodiment, each of the signal receivers may include an analog front end including an operational amplifier.

In an embodiment, the first pin may be configured to receive a signal from a host processor.

In an embodiment, the first pin may be configured to receive a driving voltage of the touch panel driver.

In an embodiment, the first pin may be connected to ground.

According to one or more embodiments of the present disclosure, a display device includes: a touch panel configured to sense a touch; and a touch panel driver configured to drive the touch panel, the touch panel driver including: pins including a first pin and a second pin configured to receive a signal corresponding to the touch from the touch panel; a first signal receiver connected to the first pin in a first use form, the first signal receiver being configured to output a first signal or a second signal according to a magnitude of an input signal of the first signal receiver; and second signal receivers including a first portion connected to the second pin, and a second portion connected to the first pin in a second use form.

In an embodiment, the display device may further include an analog-digital converter connected to at least one of the second signal receivers, the analog-digital converter being configured to convert an input signal of the analog-digital converter into a digital signal corresponding to a voltage level of the input signal of the analog-digital converter.

In an embodiment, the first signal receiver may be configured as an open-drain circuit or a push-pull circuit.

In an embodiment, each of the second signal receivers may include an analog front end including an operational amplifier.

In an embodiment, the first pin may be configured to receive a signal from a host processor in the first use form.

In an embodiment, the first pin may be configured to receive a driving voltage of the touch panel driver in the first use form.

In an embodiment, the first pin may be connected to ground in the first use form.

In an embodiment, the first pin may be configured to receive the signal corresponding to the touch from the touch panel in the second use form.

According to one or more embodiments of the present disclosure, a display device includes: a touch panel configured to sense a touch; a touch panel driver configured to drive the touch panel; a display panel configured to display an image; and a display panel driver configured to drive the display panel. The touch panel driver includes: a first pin connected to the display panel driver in a first use form; a first signal receiver connected to the first pin in the first use form, the first signal receiver being configured to output a first signal or a second signal according to a magnitude of an input signal of the first signal receiver in the first use form; and an interface circuit connected to the first pin in a second use form.

In an embodiment, the first pin may be configured to receive a synchronization signal from the display panel driver in the first use form.

In an embodiment, the first pin may be configured to receive a driving voltage of the touch panel driver in the second use form.

In an embodiment, the touch panel driver may be configured to be reset based on a signal of the first pin in the second use form.

In an embodiment, the first signal receiver may be configured as an open-drain circuit or a push-pull circuit.

In an embodiment, the touch panel driver may be configured to be reset in a software manner in the first use form, and be reset in a hardware manner in the second use form.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a view illustrating a display device in accordance with one or more embodiments of the present disclosure.

FIG. 2 is a block diagram illustrating an example of a touch panel driver shown in FIG. 1.

FIG. 3 is a circuit diagram illustrating an example of a signal receiver shown in FIG. 2.

FIG. 4 is a block diagram illustrating a touch panel driver of the display device in a first use form in accordance with one or more embodiments of the present disclosure.

FIG. 5 is a block diagram illustrating the touch panel driver shown in FIG. 4 in a second use form.

FIG. 6 is a block diagram illustrating a touch panel driver of the display device in the first use form in accordance with one or more embodiments of the present disclosure.

FIG. 7 is a block diagram illustrating the touch panel driver shown in FIG. 6 in the second use form.

FIG. 8 is a block diagram illustrating an electronic device in accordance with one or more embodiments of the present disclosure.

FIG. 9 is a view illustrating an example in which the electronic device shown in FIG. 8 is implemented as a smartphone.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Each feature of embodiments of the present disclosure may be combined or combined with each other, partially or entirely, and may be technically interlocked and operated in various ways, and each embodiment may be implemented independently of each other or in conjunction with each other.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In addition, embodiments of the present disclosure are described here with reference to schematic diagrams of ideal embodiments (and intermediate structures) of the present disclosure, so that changes in a shape as shown due to, for example, manufacturing technology and/or a tolerance may be expected. Therefore, the present disclosure shall not be limited to the specific shapes of a region shown in the drawings, but may include shape deviations caused by, for example, the manufacturing technology. The regions shown in the drawings are schematic in nature, and the shapes thereof do not represent the actual shapes of the regions of the device, and do not limit the scope of the present disclosure.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

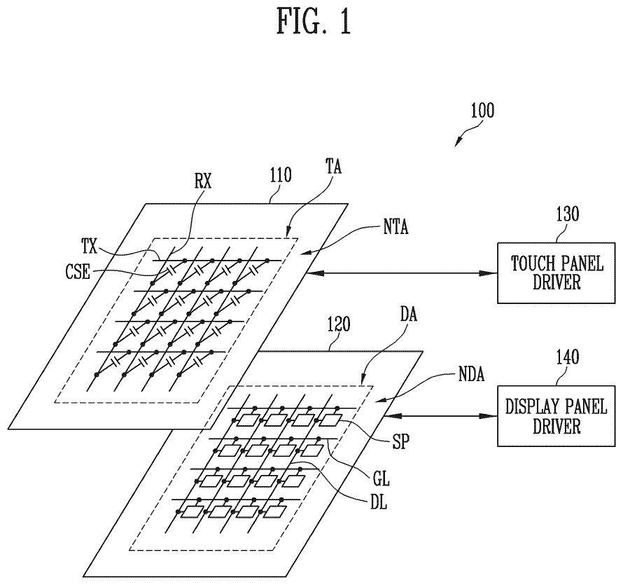

FIG. 1 is a view illustrating a display device in accordance with one or more embodiments of the present disclosure.

Referring to FIG. 1, the display device 100 may include a touch panel 110, a display panel 120, a touch panel driver 130, and a display panel driver 140.

In FIG. 1, the touch panel 110 and the display panel 120 are illustrated as separated from each other. However, this is illustrated for convenience in showing the functionally of the touch panel 110 distinguished from the functionality of the display panel 120 in the display device 100. For example, the touch panel 100 may be formed through a process separate from a process through which the display panel 120 is formed, such that the touch panel 110 and the display panel 120 are connected to (e.g., coupled to or attached to) each other (e.g., the touch panel 110 is attached and coupled to one surface of the display panel 120). In other words, the touch panel 110 may be formed as an add-on touch panel. In other embodiments, the touch panel 110 may be formed with the display panel 120 through one process (e.g., a process of manufacturing the display panel 120). In other words, the touch panel 110 may be formed as an in-cell touch panel.

The touch panel 110 may be provided on one surface of the display panel 120. For example, the touch panel 110 may be disposed on one surface (e.g., on an upper surface) selected from among both surfaces (e.g., opposite surfaces) of the display panel 120, and the one surface may be a surface in a direction in which an image is displayed. In another embodiment, the touch panel 110 may be directly formed on at least one surface selected from both the surfaces of the display panel 120, or may be formed inside the display panel 120. For example, the touch panel 110 may be directly formed on an outer surface of an upper substrate or a lower substrate of the display panel (e.g., an upper surface of the upper substrate or a lower surface of the lower substrate), or may be directly formed on an inner surface of the upper substrate (e.g., a lower surface of the upper substrate) or an inner surface of the lower substrate (e.g., an upper surface of the lower substrate).

The touch panel 110 may include a touch area TA capable of sensing a touch, and a non-touch area NTA disposed at an outside of the touch area TA (e.g., a peripheral area or an edge area of the touch area TA). In an embodiment, the touch area TA may be disposed to correspond to a display area DA of the display panel 120.

In an embodiment, the touch panel 110 may be disposed while at least one area of the touch panel 110 overlaps with the display panel 120. For example, the touch area TA of the touch panel 110 may be disposed on the display area DA of the display panel 120. In an embodiment, at least one electrode for detecting a touch may be disposed in the touch area TA. The at least one electrode for detecting the touch may include a first touch electrode TX and a second touch electrode RX. The first touch electrode TX and the second touch electrode RX may be provided on the display area DA of the display panel 120.

Lines for electrically connecting the at least one electrode provided in the touch area TA to the touch panel driver 130 may be disposed in the non-touch area NTA. For example, lines for electrically connecting the first touch electrode TX and the second touch electrode RX to the touch panel driver 130 may be disposed in the non-touch area NTA. The non-touch area NTA may be disposed to correspond to a non-display area NDA of the display panel 120.

The touch panel 110 may include at least one first touch electrode TX and at least one second touch electrode RX, which are provided in the touch area TA. For example, the touch panel 110 may include a first touch electrode TX and a second touch electrode RX crossing or intersecting the first touch electrode TX. In some embodiments, the first touch electrode TX may extend along a first direction, and the second touch electrode RX may extend along a second direction crossing or intersecting the first direction, while being insulated from the first touch electrode TX by an insulating layer. A capacitor CSE may be formed between the first touch electrode TX and the second touch electrode RX. A capacitance between the first touch electrode TX and the second touch electrode RX may be changed when a touch occurs at a corresponding point or the periphery thereof. Therefore, the touch panel driver 130 may detect a change in a capacitance between the first touch electrode TX and the second touch electrode RX, thereby sensing a touch.

However, the present disclosure is not limited to the shape, size, and/or arrangement direction of the first touch electrode TX and the second touch electrode RX.

The display panel 120 may include the display area DA, and the non-display area NDA located at an outside of the display area DA (e.g., an edge area or a peripheral area of the display area DA).

A gate line GL and a data line DL may be disposed in the display area DA, and a sub-pixel SP that is electrically connected to the gate line GL and the data line DL may be disposed in the display area DA. Lines for supplying various driving signals and/or power, which are used to drive the sub-pixel SP, may be provided in the non-display area NDA.

However, the present disclosure is not limited to the kind of the display panel 120. For example, the display panel 120 may be a self-luminous display panel. For example, the display panel 120 may include a plurality of light emitting elements. For example, the light emitting element may be an organic light emitting diode. For example, the light emitting element may be an inorganic light emitting diode, such as a micro LED (light emitting diode) or a quantum dot light emitting diode. For example, the display panel 120 may be a non-light emitting display panel, such as a Liquid Crystal Display (LCD) panel, an Electro-Phoretic Display (EPD) panel, or an Electro-Wetting Display (EWD) panel. When the display panel 120 is the non-light emitting display panel, the display device 100 may further include a backlight unit (e.g., a backlight or backlight panel) for supplying light to the display panel 120.

The touch panel driver 130 may be connected to the touch panel 110 to transmit a signal input to the touch panel 110 or receive a signal output from the touch panel 110. The touch panel driver 130 may supply a touch driving signal to the touch panel 110, and then receive a touch sensing signal corresponding to the touch driving signal from the touch panel 110, thereby detecting a touch. As such, the touch panel driver 130 may include a touch driving signal transmitter and a touch sensing signal receiver. In an embodiment, the touch driving signal transmitter and the touch sensing signal receiver may be integrated into one (e.g., the same) Integrated Circuit (IC), but the present disclosure is not limited thereto. In an embodiment, the touch panel driver 130 (e.g., the touch driving signal transmitter) may concurrently or substantially simultaneously (or sequentially) supply a touch driving signal to a plurality of first touch electrodes TX. The touch panel driver 130 (e.g., the touch sensing signal receiver) may receive a touch sensing signal (e.g., a signal corresponding to a touch) from a plurality of second sensing electrode RX. The touch panel driver 130 may receive a touch sensing signal from the touch panel 110, and perform signal processing on the touch sensing signal, thereby detecting whether a touch has been input and/or a coordinate of the touch.

In the present embodiment, the touch panel 110 has been described as being driven using a mutual capacitance method. However, the present disclosure is not limited to the driving method of the touch panel 110.

The display panel driver 140 may be connected to the display panel 120 to supply a signal input to the display panel 120 or receive a signal output from the display panel 120. The display panel driver 140 may supply a gate signal to the gate line GL, and may supply a data voltage to the data line DL.

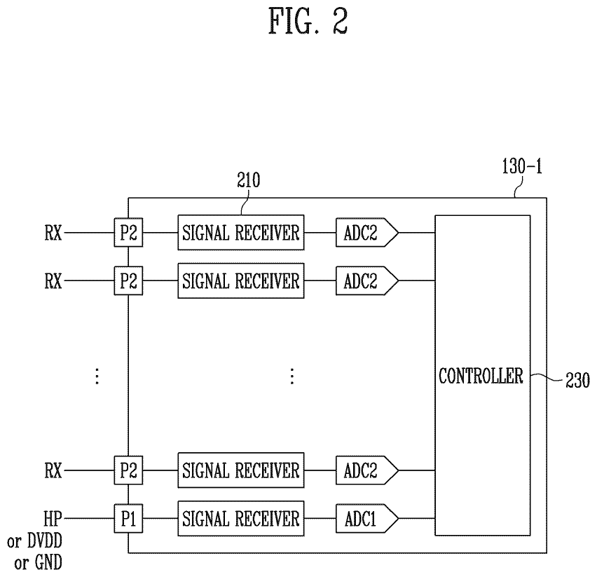

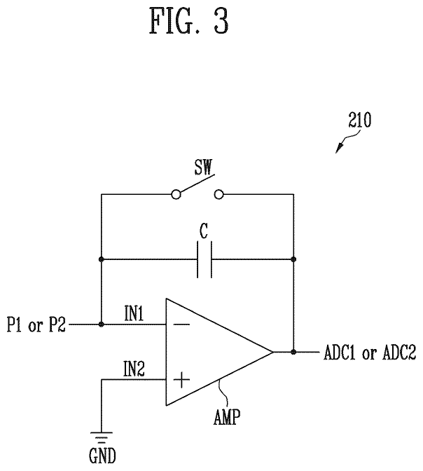

FIG. 2 is a block diagram illustrating an example of the touch panel driver shown in FIG. 1. FIG. 3 is a circuit diagram illustrating an example of a signal receiver shown in FIG. 2.

For convenience of illustration, first and second pins P1 and P1, a signal receiver 210, analog-digital converters ADC1 and ADC2, and a controller 230 are shown in FIG. 2, and other components may not be illustrated.

Referring to FIGS. 2 and 3, a touch panel driver 130-1 may include a first pin P1, a second pin P2 for receiving a signal corresponding to a touch from the touch panel 110 (e.g., see FIG. 1), signal receivers 210 connected to the pins P1 and P2, respectively, and analog-digital converters ADC1 and ADC2 connected to the signal receivers 210, respectively.

The first pin P1 and the second pin P2 may be respectively connected to the signal receivers having the same or substantially the same configuration as each other. In an embodiment, the signal receiver 210 may be implemented as an analog front end (AFE) including an operational amplifier AMP. For example, a first input terminal IN1 (e.g., an inverting input terminal) of the operational amplifier AMP may be electrically connected to the pin P1 or P2, a second input terminal IN2 (e.g., a non-inverting input terminal) of the operational amplifier AMP may be electrically connected to ground GND, an output terminal of the operational amplifier AMP may be connected to the analog-digital converter ADC1 or ADC2, and a capacitor C and a switch SW may be connected between the first input terminal IN1 and the output terminal of the operational amplifier AMP.

The signal receiver 210 connected to the first pin P1 may be connected to a first analog-digital converter ADC1. The first analog-digital converter ADC1 may convert an analog signal input from the signal receiver 210 into a digital signal.

In an embodiment, the first pin P1 may perform a function of a general purpose input/output (GPIO) pin. For example, the first pin P1 may receive a synchronization signal.

When the first pin P1 receives the synchronization signal, the touch panel driver 130-1 may recognize the signal input to the first pin P1 as a high signal or a low signal. Therefore, the touch panel driver 130-1 may recognize the signal input to the first pin P1 as the high signal or the low signal through the first analog-digital converter ADC1. For example, the first analog-digital converter ADC1 may output the high signal or the low signal according to a magnitude of an input signal (e.g., a signal of the signal receiver 210 connected to the first pin P1). For example, the first analog-digital converter ADC1 may output the high signal when the input signal is a reference voltage or higher, and may output the low signal when the input signal (e.g., the signal of the signal receiver 210 connected to the first pin P1) is the reference voltage or lower. The reference voltage may be a suitable or predetermined voltage.

In an embodiment, the first pin P1 may receive a signal from a host processor HP. For example, the host processor HP may include at least one of a central processing unit (CPU) or an application processor (AP). The host processor HP may further include at least one of a graphic processing unit (GPU), a communication processor (CP), and/or an image signal processor (ISP). The host processor HP may further include a neural processing unit (NPU).

For example, the first pin P1 may receive a wake-up signal from the host processor HP. For example, the controller 230 may start an operation of the touch panel driver 130-1 or start communication with the host processor HP in synchronization with the wake-up signal. The touch panel driver 130-1 may provide the host processor HP with data on a touch (e.g., whether the touch has been input, an intensity of the touch, a coordinate of the touch, and the like). However, the present disclosure is not limited to the kind of signal received by the first pin P1 from the host processor HP.

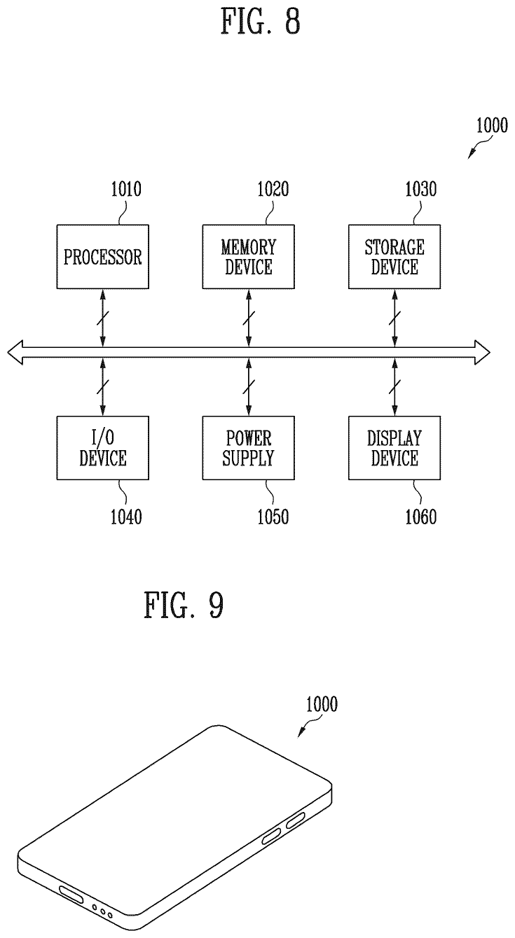

In an embodiment, the first pin P1 may receive a driving voltage DVDD of the touch panel driver 130-1. For example, the first pin P1 may receive the driving voltage DVDD from a power supply 1050 (e.g., see FIG. 8), which will be described in more detail below.

The controller 230 may check a driving state of the touch panel driver 130-1 based on an output signal of the first analog-digital converter ADC1. For example, when a high voltage is applied from the first analog-digital converter ADC1, the controller 230 may determine the driving state as a state in which the touch panel driver 130-1 is being operated. In addition, the driving voltage DVDD used as a power voltage for driving the touch panel driver 130-1 may be applied to the touch panel driver 130-1 through a separate power pin instead of the first pin P1.

In an embodiment, the first pin P1 may be connected to ground GND. For example, when the first pin P1 is not used (e.g., is unnecessary), the first pin P1 may be connected to ground GND.

As such, the display device may allow an analog-digital converter (e.g., the first analog-digital converter ADC1) connected to at least one pin (e.g., the first pin P1) from among the pins configured to receive a touch signal, such as the existing second pin P2, to output the high signal or the low signal, so that the at least one pin can be used as a GPIO pin.

The signal receiver 210 connected to the second pin P2 may be connected to a second analog-digital converter ADC2. The second analog-digital converter ADC2 may convert an analog signal input from the signal receiver 210 into a digital signal. The second analog-digital converter ADC2 may convert an input signal (e.g., a signal of the signal receiver 210 connected to the second pin P2) into a digital signal corresponding to a voltage level of the input signal. The controller 230 may detect whether a touch has been input, an intensity of the touch, a coordinate of the touch, and the like, based on an output signal of the second analog-digital converter ADC2.

In the present embodiment, the second analog-digital converters ADC2 of which a number thereof corresponds to a number of the second touch electrodes RX are illustrated as being provided to correspond one-to-one to the second touch electrodes RX. However, the present disclosure is not limited thereto. For example, a plurality of second touch electrodes RX may share one second analog-digital converter ADC2. A switching circuit (e.g., a 1: N multiplexer) may be provided between the signal receivers 210 and the second analog-digital converter ADC2.

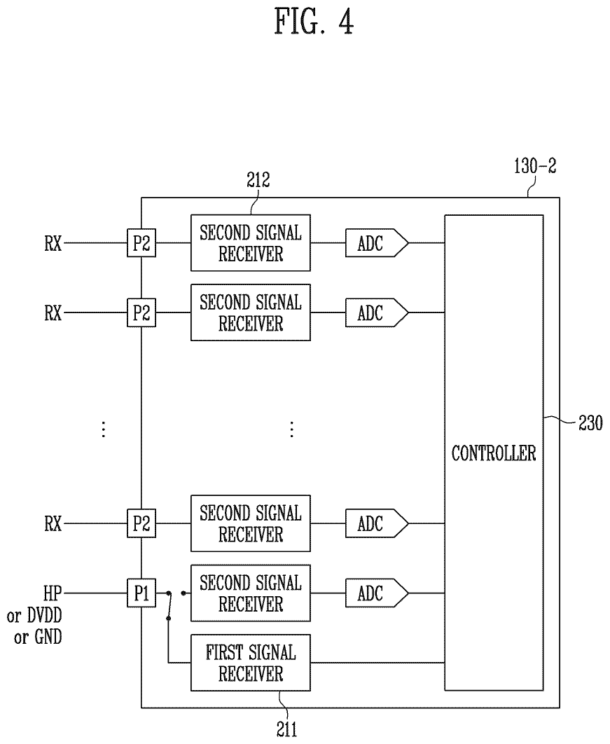

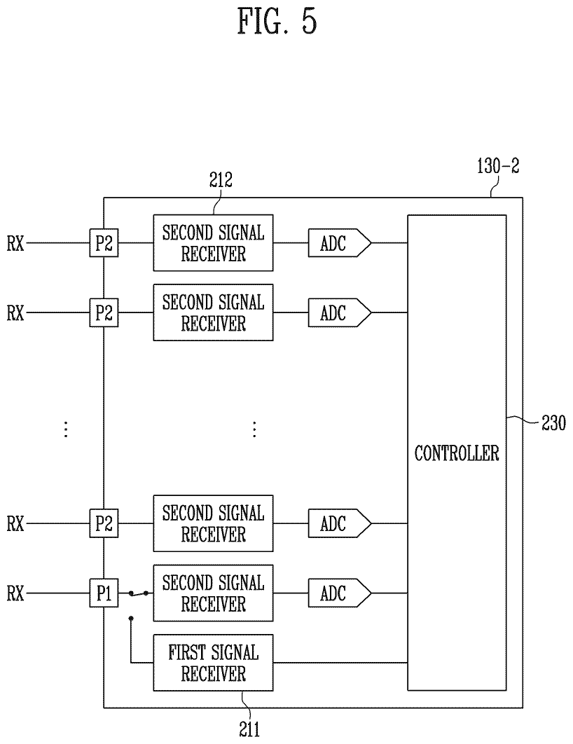

FIG. 4 is a block diagram illustrating a touch panel driver of the display device in a first use form in accordance with one or more embodiments of the present disclosure. FIG. 5 is a block diagram illustrating the touch panel driver shown in FIG. 4 in a second use form.

The touch panel driver in accordance with the present embodiments may be the same or substantially the same as the touch panel driver described above with reference to FIG. 2, except components related to the first pin P1 may be different. Therefore, the components that are the same or substantially the same as (or similar to) those described above with reference to FIG. 2 are designated by like reference numerals, and thus, redundant description thereof may not be repeated.

For convenience of illustration, the first and second pins P1 and P1, first and second signal receivers 211 and 212, an analog-digital converter ADC, and a controller 230 are shown in FIGS. 4 and 5, and other components may not be illustrated.

Referring to FIGS. 4 and 5, the first pin P1 may be connected to the first signal receiver 211 in the first use form, and may be connected to the second signal receiver 212 in the second use form. The second pin P2 may be connected to the second signal receiver 212. In addition, the first signal receiver 211 may be connected to the controller 230, and the second signal receiver 212 may be connected to the analog-digital converter ADC.

Referring to FIG. 4, the first pin P1 may be connected to the first signal receiver 211 in the first use form. The first pin P1 may perform a function of a GPIO pin in the first use form. For example, the first pin P1 may receive a synchronization signal.

When the first pin P1 receives the synchronization signal, the touch panel driver 130-2 may recognize the signal input to the first pin P1 as a high signal or a low signal. Therefore, the touch panel driver 130-2 may recognize the signal input to the first pin P1 as the high signal or the low signal through the first signal receiver 211. For example, the first signal receiver 211 may output the high signal or the lower signal according to a magnitude of an input signal (e.g., a signal of the first pin P1). For example, the first signal receiver 211 may be configured as an open-drain circuit or a push-pull circuit. However, the first signal receiver 211 in accordance with the present disclosure is not limited to the open-drain circuit and the push-pull circuit.

A function of the first pin P1 in the first use form may be the same or substantially the same as the function of the first pin P1 described above with reference to FIG. 2, and therefore, redundant description thereof may not be repeated.

Referring to FIG. 5, the first pin P1 may be connected to the second signal receiver 212 in the second use form. The second signal receiver 212 may be the same or substantially the same as the signal receiver 210 described above with reference to FIGS. 2 and 3, and the analog-digital converter ADC may be the same or substantially the same as the second analog-digital converter ADC2 described above with reference to FIG. 2. Therefore, redundant description thereof may not be repeated.

A function of the first pin P1 in the second use form may be the same or substantially the same as the function of the second pin P2 described above with reference to FIG. 2, and therefore, redundant description thereof may not be repeated.

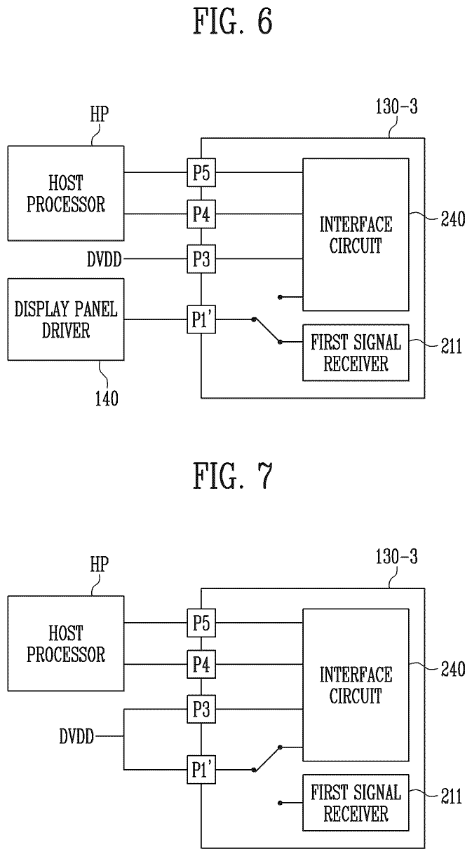

FIG. 6 is a block diagram illustrating a touch panel driver of the display device in the first use form in accordance with one or more embodiments of the present disclosure. FIG. 7 is a block diagram illustrating the touch panel driver shown in FIG. 6 in the second use form.

For convenience of illustration, first and third to fifth pins P1′, P3, P4, and P5, an interface circuit 240, and a first signal receiver 211 are shown in FIGS. 6 and 7, and other components may not be illustrated.

Referring to FIGS. 6 and 7, the touch panel driver 130-3 may include a first pin P1′, a third pin P3 for receiving a driving voltage DVDD of the touch panel driver 130-3, fourth and fifth pins P4 and P5 for communicating with a host processor HP, a first signal receiver 211, and an interface circuit 240 for communicating with the touch panel driver 130-3.

In an embodiment, the interface circuit 240 may be a circuit for an inter-integrated circuit (I2C) interface. For example, the I2C interface is a signal transmission interface for transmitting/receiving data through two lines of a serial clock (SLC) signal line and a serial data (SDA) signal line. The I2C interface is a serial communication interface, and may synchronize a clock through the SLC signal line (e.g., a signal line connected to the fourth pin P4), and perform an input/output of data through the SDA signal line (e.g., a signal line connected to the fifth pin P5). In addition, the I2C interface may receive an interrupt signal through an interrupt signal line (e.g., a signal line connected to the third pin P3), and a driving voltage DVDD may be used as the interrupt signal.

Referring to FIG. 6, the first pin P1′ may be connected to the first signal receiver 211 in the first use form. The first pin P1′ may be connected to the display panel driver 140 in the first use form. The first pin P1′ may perform a function of a GPIO pin in the first use form. For example, the first pin P1′ may receive a synchronization signal for synchronizing the display panel driver 140 and the touch panel driver 130-3 with each other.

When the first pin P1′ receives the synchronization signal, the touch panel driver 130-3 may recognize a signal input to the first pin P1′ as a high signal or a low signal. Therefore, the touch panel driver 130-3 may recognize the signal input to the first pin P1′ as the high signal or the low signal through the first signal receiver 211. For example, the first signal receiver 211 may output the high signal or the low signal according to a magnitude of an input signal (e.g., a signal of the first pin P1′). For example, the first signal receiver 211 may be configured as an open-drain circuit or a push-pull circuit. However, the first signal receiver 211 in accordance with the present disclosure is not limited to the open-drain circuit and the push-pull circuit.

The touch panel driver 130-3 may be reset in a software manner in the first use form. In other words, in the touch panel driver 130-3, unlike the second use form described in more detail below, a voltage for resetting may not be applied through the first pin P1′ in the first use form.

Referring to FIG. 7, the first pin P1′ may be connected to the interface circuit 240 in the second use form. The first pin P1′ may receive the driving voltage DVDD of the touch panel driver 130-3 in the second use form.

The touch panel driver 130-3 may be reset in a hardware manner in the second use form. For example, when the touch panel driver 130-3 is not driven, the driving voltage DVDD may not be applied to the first pin P1′ (e.g., a voltage of OV or a low voltage may be applied). The voltage applied to the first pin P1′ may be used as a reset voltage, and the touch panel driver 130-3 may be reset.

As such, when the touch panel driver 130-3 is reset in the software manner, the existing pin for resetting (e.g., the first pine P1′) is not required. As such, in the display device, the first signal receiver 211 is connected to a pin for resetting, so that the pin for resetting may be used as a GPIO pin.

FIG. 8 is a block diagram illustrating an electronic device in accordance with one or more embodiments of the present disclosure. FIG. 9 is a view illustrating an example in which the electronic device shown in FIG. 8 is implemented as a smartphone.

Referring to FIGS. 8 and 9, the electronic device 1000 may include a processor 1010, a memory device 1020, a storage device 1030, an input/output (I/O) device 1040, a power supply 1050, and a display device 1060. The display device 1060 may be the display device described above with reference to FIG. 1. Also, the electronic device 1000 may further include several ports capable of communicating with a video card, a sound card, a memory card, a USB device, and the like, and/or communicating with other systems. In an embodiment, as shown in FIG. 9, the electronic device 1000 may be implemented as a smartphone. However, the present disclosure is not limited thereto, and the electronic device 1000 may have various suitable forms. For example, the electronic device 1000 may be implemented as a mobile phone, a video phone, a smart pad, a smart watch, a tablet PC, a vehicle navigation system, a computer monitor, a notebook computer, a head mounted display device, or the like.

The processor 1010 may be the host processor HP (see FIG. 2) described above. The processor 1010 may be connected to other components through an address bus, a control bus, a data bus, and the like. In some embodiments, the processor 1010 may be connected to an extension bus, such as a peripheral component interconnect (PCI) bus.

The memory device 1020 may store data used for an operation of the electronic device 1000. For example, the memory device 1010 may include a nonvolatile memory device, such as an Erasable Programmable Read-Only Memory (EPROM) device, an Electrically Erasable Programmable Read-Only Memory (EEPROM) device, a flash memory device, a Phase Change Random Access Memory (PRAM) device, a Resistance Random Access Memory (RRAM) device, a Nano Floating Gate Memory (NFGM) device, a Polymer Random Access Memory (PoRAM) device, a Magnetic Random Access Memory (MRAM) device, or a Ferroelectric Random Access Memory (FRAM) device, and/or a volatile memory device, such as a Dynamic Random Access Memory (DRAM) device, a Static Random Access Memory (SRAM) device, or a mobile DRAM device.

The storage device 1030 may include a Solid State Drive (SSD), a Hard Disk Drive (HDD), a CD-ROM, and the like.

The I/O device 1040 may include an input means, such as a keyboard, a keypad, a touch screen, or a mouse, and an output means, such as a speaker or a printer. In some embodiments, the display device 1060 may be included in the I/O device 1040.

The power supply 1050 may supply power used for an operation of the electronic device 1000. For example, the power supply 1050 may be a power management integrated circuit (PMIC).

The display device 1060 may display an image corresponding to visual information of the electronic device 1000. The display device 1060 may be an organic light emitting display device or a quantum dot light emitting display device, but the present disclosure is not limited thereto. The display device 1060 may be connected to other components through the buses or another communication link.

Embodiments of the present disclosure may be applied to display devices and electronic devices including the same. For example, embodiments of the present disclosure may be applied to digital TVs, 3D TVs, mobile phones, smartphones, tablet computers, VR devices, PCs, home appliances, notebook computers, PDAs, PMPs, digital cameras, music players, portable game consoles, navigation systems, and the like.

In the display device in accordance with one or more embodiments of the present disclosure, a pin for recognizing a touch signal (e.g., a signal corresponding to a touch) or a pin connected to an interface circuit may be utilized for another use, so that there may be no unnecessarily left pin. Accordingly, the use of a touch panel driver having an excessively large size may be prevented, and cost of the display device may be reduced.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a touch panel configured to sense a touch; and
a touch panel driver configured to drive the touch panel, the touch panel driver comprising:
pins comprising a first pin and a second pin configured to receive a signal corresponding to the touch from the touch panel;
signal receivers connected to the pins, respectively; and
a first analog-digital converter connected to a signal receiver connected to the first pin from among the signal receivers, the first analog-digital converter being configured to output a first signal or a second signal according to a magnitude of an input signal of the first analog-digital converter.

2. The display device of claim 1, further comprising a second analog-digital converter connected to a signal receiver connected to the second pin from among the signal receivers, the second analog-digital converter being configured to convert an input signal of the second analog-digital converter into a digital signal corresponding to a voltage level of the input signal of the second analog-digital converter.

3. The display device of claim 1, wherein each of the signal receivers comprises an analog front end comprising an operational amplifier.

4. The display device of claim 1, wherein the first pin is configured to receive a signal from a host processor.

5. The display device of claim 1, wherein the first pin is configured to receive a driving voltage of the touch panel driver.

6. The display device of claim 1, wherein the first pin is connected to ground.

7. A display device comprising:
a touch panel configured to sense a touch; and
a touch panel driver configured to drive the touch panel, the touch panel driver comprising:
pins comprising a first pin and a second pin configured to receive a signal corresponding to the touch from the touch panel;
a first signal receiver connected to the first pin in a first use form, the first signal receiver being configured to output a first signal or a second signal according to a magnitude of an input signal of the first signal receiver; and
second signal receivers comprising a first portion connected to the second pin, and a second portion connected to the first pin in a second use form.

8. The display device of claim 7, further comprising an analog-digital converter connected to at least one of the second signal receivers, the analog-digital converter being configured to convert an input signal of the analog-digital converter into a digital signal corresponding to a voltage level of the input signal of the analog-digital converter.

9. The display device of claim 7, wherein the first signal receiver is configured as an open-drain circuit or a push-pull circuit.

10. The display device of claim 7, wherein each of the second signal receivers comprises an analog front end comprising an operational amplifier.

11. The display device of claim 7, wherein the first pin is configured to receive a signal from a host processor in the first use form.

12. The display device of claim 7, wherein the first pin is configured to receive a driving voltage of the touch panel driver in the first use form.

13. The display device of claim 7, wherein the first pin is connected to ground in the first use form.

14. The display device of claim 7, wherein the first pin is configured to receive the signal corresponding to the touch from the touch panel in the second use form.

15. A display device comprising:
a touch panel configured to sense a touch;
a touch panel driver configured to drive the touch panel;
a display panel configured to display an image; and
a display panel driver configured to drive the display panel,
wherein the touch panel driver comprises:
a first pin connected to the display panel driver in a first use form;
a first signal receiver connected to the first pin in the first use form, the first signal receiver being configured to output a first signal or a second signal according to a magnitude of an input signal of the first signal receiver in the first use form; and
an interface circuit connected to the first pin in a second use form.

16. The display device of claim 15, wherein the first pin is configured to receive a synchronization signal from the display panel driver in the first use form.

17. The display device of claim 15, wherein the first pin is configured to receive a driving voltage of the touch panel driver in the second use form.

18. The display device of claim 15, wherein the touch panel driver is configured to be reset based on a signal of the first pin in the second use form.

19. The display device of claim 15, wherein the first signal receiver is configured as an open-drain circuit or a push-pull circuit.

20. The display device of claim 15, wherein the touch panel driver is configured to be reset in a software manner in the first use form, and be reset in a hardware manner in the second use form.
